(19) United States
(12) Patent Application Publication
(10) Pub. No.: US 2005/0046340 A1
(43) Pub. Date: Mar. 3, 2005

(54) OLED display and production method thereof

(76) Inventors: Sayuri Kohara, Yamato-shi (JP); Koji Murayama, Yamato-shi (JP); Atsushi Tanaka, Yasu-gun (JP)

Correspondence Address: Karl F. Milde, Jr., Esq.;MILDE & HOFFBERG, L.L.P., Suite 460, 10 Bank Street, White Plains, NY, 10606, US

(21) Appl. No.: 10/926,264

(22) Filed: Aug. 25, 2004

(30) Foreign Application Priority Data
Aug. 28, 2003 (JP) 2003-209198

(51) Int. Cl. H01J 1/62

(52) U.S. Cl. 313/504

(57) ABSTRACT

An OLED display 10 comprises: a device substrate 12; a plurality of OLED devices 14 which are arranged in the form of a matrix on the device substrate 12; a rib 16 which is provided on the device substrate 12 in such a manner that the rib 16 encloses the respective OLED devices 14; an encapsulation substrate 18 which is placed opposite to the device substrate 12 and which is brought into intimate contact with the rib 16; and a sealant 20 which is provided between a marginal area of the device substrate 12 and a marginal area of the encapsulation substrate 18 so as to encapsulate both the OLED devices 14 and the rib 16.

### BACKGROUND OF THE INVENTION

1. Field of the Invention

The present invention relates to an OLED (organic light emitting diode) display comprising OLED devices and a production method thereof.

2. Description of Related Art

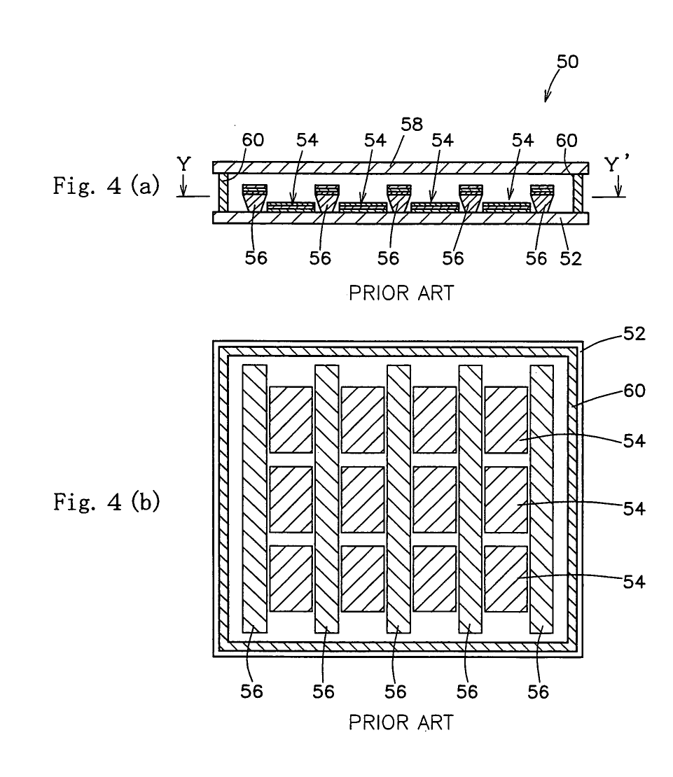

As shown in FIGS. 4(a) and 4(b), in a known OLED display 50, OLED devices 54 are arranged in the form of a matrix on a device substrate 52. In each OLED device 54, an organic light emitting layer is sandwiched between an anode electrode and a cathode electrode. The device substrate 52 and an encapsulation substrate 58 (or also called “encapsulation cap”) are placed opposite to each other, and a marginal area of the device substrate 52 and a marginal area of the encapsulation substrate 58 are bonded together by a sealant 60 so as to encapsulate the OLED devices 54. As shown in FIG. 4(b), ribs 56 are provided in a longitudinal direction of the device substrate 52. As the device substrate 52 and the encapsulation substrate 58, a glass substrate and a metal cap are used. In the OLED display 50, an image is displayed by light emitted from the OLED devices 54. In a bottom-emission structure, the light is emitted through the device substrate 52. On the contrary, in a top-emission structure, the light is emitted through the encapsulation substrate 58.

The OLED devices 54 are degraded by reaction with moisture or oxygen or by reaction with gas emitted from the sealant 60 when the sealant 60 is hardened. Moisture permeability of the sealant 60 and poor adhesion between the sealant 60 and the substrates 52 and/or 58 causes the moisture and oxygen to get into the OLED display 50. When one of the OLED devices is degraded due to moisture and oxygen, this leads to the degradation of all the OLED devices 54. As a result, the brightness of the entire display 50 is reduced.

It is necessary that the device substrate 52 and the encapsulation substrate 58 are placed opposite to each other at a constant distance. When the distance between the substrates 52 and 58 is changed, an interference pattern appears on a display screen of the OLED display 50. If the display 50 is a relatively small screen display, it is easy to make the distance between the substrates 52 and 58 constant. However, in the case of a large-screen display 50, it is not sufficient to apply the sealant 60 on the marginal areas of the substrates 52 and 58, because the distance between the substrates 52 and 58 is nonuniform and an interference pattern appears. Unlike an LCD (liquid crystal display), the display 50 comprises a gas layer of nitrogen or the like, so that the display 50 is easily deformed. Therefore, the application of sealant only to the marginal areas of the substrates 52 and 58 causes a defect in such display 50.

When a spacer is provided at a predetermined position of the display 50, the distance between the substrates 52 and 58 can be made constant. However, the spacer cannot prevent the entry of moisture and oxygen into the display 50, so that it cannot prevent the degradation of the display 50.

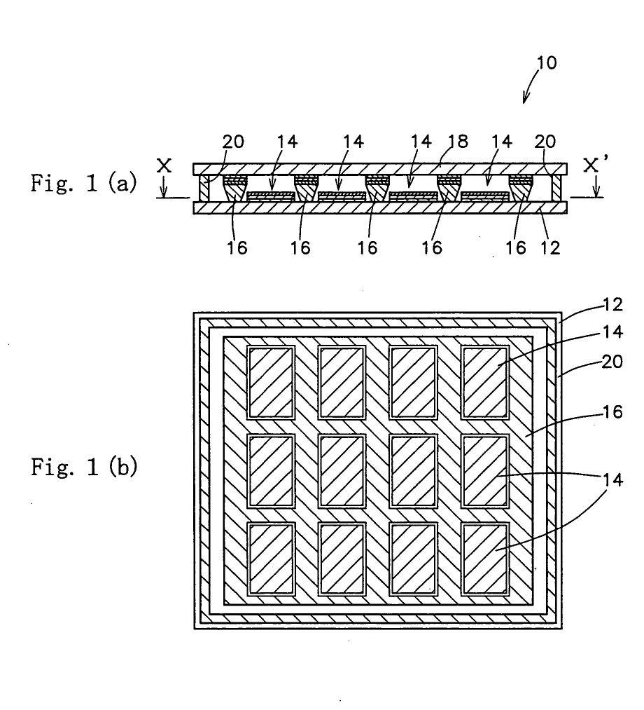

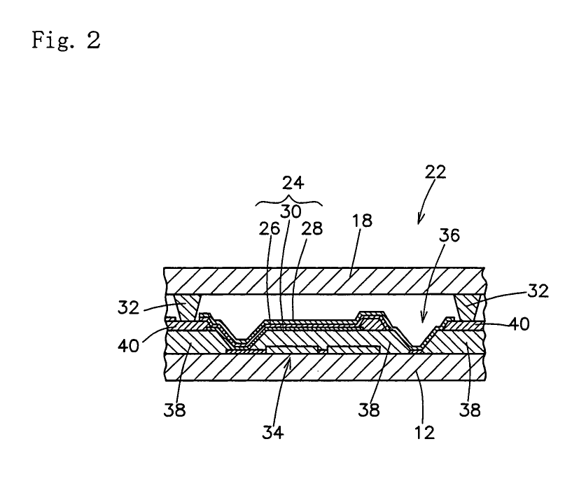

A patent document 1 discloses an OLED display in which a frame is provided along the inner perimeter of the sealant. By depressurizing a space enclosed by the frame and the encapsulation substrate (or a cover), residual moisture and oxygen can be reduced and the degradation of the OLED device can be prevented. Thus, the frame provided along the inner perimeter of a sealant can prevent oxygen from entering into the OLED display. However,. in the case where the OLED display is upsized, it is difficult to make a distance between the substrates constant. If the OLED display has a top-emission structure, an interference pattern appears on the encapsulation substrate (or display screen), so that the display quality is degraded.

[Document 1] Japanese Unexamined Patent Publication No. (Patent Kokai No.) 2000-195675 (FIG. 1 and FIG. 2)

### SUMMARY OF THE INVENTION

An OLED display of the present invention comprises: a device substrate; a plurality of OLED devices which are arranged in the form of a matrix on the device substrate; a rib which is provide on the device substrate in such a manner that the rib encloses the respective OLED devices or respective groups of the OLED devices; an encapsulation substrate which is placed opposite to the device substrate and which is brought into intimate contact with the rib; and a sealant which is provided between a marginal area of the device substrate and a marginal area of the encapsulation substrate so as to encapsulate both the OLED devices and the rib. The rib is provided around the OLED devices and is brought into intimate contact with the encapsulation substrate. The OLED devices are encapsulated by the device substrate, the encapsulation substrate, and the rib.

A method of producing an OLED display according to the present invention comprises: preparing a device substrate and an encapsulation substrate; forming a plurality of OLED devices in the form of a matrix on the device substrate; forming a rib on the device substrate in such a manner that the rib encloses the respective OLED devices or respective groups of the OLED devices; bringing the rib and the encapsulation substrate into intimate contact with each other; and encapsulating the OLED devices by a sealant which is provided between a marginal area of the device substrate and a marginal area of the encapsulation substrate. BRIEF DESCRIPTION OF THE DRAWINGS

FIG. 1(a) is a sectional view of an OLED display of the present invention, and FIG. 1(b) is a plan view taken on line X-X′ of FIG. 1(a).

FIG. 2 is a sectional view of an active-matrix OLED display.

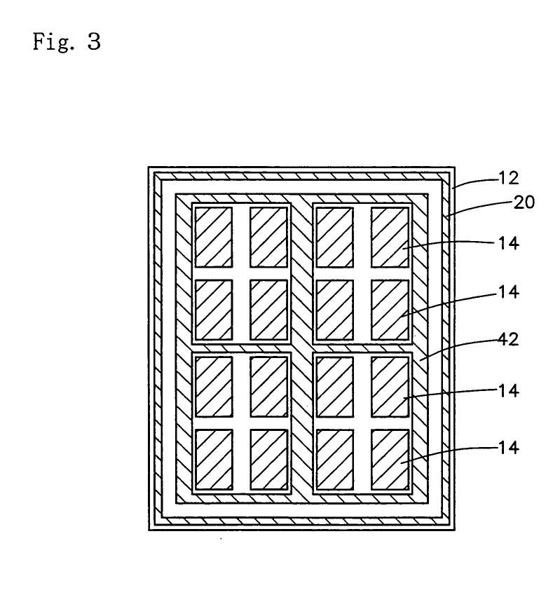

FIG. 3 is a plan view of an OLED display in which respective groups of the OLED devices are enclosed by a rib.

FIG. 4(a) is a sectional view of a conventional OLED display, and FIG. 4(b) is a plan view taken on line Y-Y′ of FIG. 4(a).

### DESCRIPTION OF THE PREFERRED EMBODIMENTS

An OLED display and a production method thereof will be described with reference to the drawings.

As shown in FIGS. 1(a) and 1(b), an OLED display 10 of the present invention comprises: a device substrate 12; a plurality of OLED devices 14 which are arranged in the form of a matrix on the device substrate 12; a rib 16 which is provided on the device substrate 12 in such a manner that the rib 16 encloses the respective OLED devices 14; an encapsulation substrate 18 which is placed opposite to the device substrate 12 and which is brought into intimate contact with the rib 16; and a sealant 20 which is provided between a marginal area of the device substrate 12 and a marginal area of the encapsulation substrate 18 so as to encapsulate both the OLED devices 14 and the rib 16.

The device substrate 12 is an insulating substrate such as glass. A plurality of OLED devices 14 are arranged in the form of a matrix on the device substrate 12. Each OLED device 14 is sandwiched between an anode electrode and a cathode electrode.

In FIG. 1, the OLED devices 14 appears to be provided directly on the device substrate 12. However, in practice, signal lines or the like are provided on the device substrate 12 and the OLED devices 14 are provided on the signal lines through an insulating material, as described later. In the specification and the drawings of the present invention, such signal lines and insulating material are omitted.

When the OLED display 10 is a passive-matrix OLED display, scanning lines and signal lines are arranged in the form of a matrix on the substrate 12 and connected to anode electrodes and cathode electrodes, respectively. When the OLED display 10 is an active-matrix OLED display, scanning lines and signal lines are arranged in the form of a matrix on the substrate 12 and active devices such as a TFT (thin film transistor) are formed at the intersections between the scanning lines and the signal lines. A gate of the TFT is connected to the scanning line, a source of the TFT is connected to the signal line, and a drain of the TFT is connected to the anode electrode.

The rib 16 is provided in such a manner that the rib 16 encloses the respective OLED devices 14. As the rib 16, resin such as negative photoresist is used. More specifically, examples of such resin include novolak resin and cresol resin.

The lower surface of the encapsulation substrate 18 and the top of the rib 16 are brought into intimate contact with each other. The OLED devices 14 are encapsulated by the device substrate 12, the encapsulation substrate 18, and the rib 16. Further, the sealant 20 is provided between a marginal area of the device substrate 12 and a marginal area of the encapsulation substrate 18 so as to connect the both substrates 12 and 18. In the OLED display 10, both the rib 16 and the OLED devices 14 are encapsulated.

Compared to a conventional OLED display, there is less possibility that oxygen and moisture reach to the OLED devices 14. Also, there is less possibility that a reaction gas emitted from the sealant 20 reaches to the OLED devices 14. The distance between the device substrate 12 and the encapsulation substrate 18 is made constant by making the height of the rib 16 constant. In the top-emission OLED display 10, no interference pattern appears on the encapsulation substrate 18 and therefore a display quality can be increased.

A surface of the encapsulation substrate 18 of the aforementioned OLED display 10 may be UV (ultraviolet rays)/ozone-treated, plasma-treated, or treated with a silane coupling agent. Since the treated surface of the encapsulation substrate 18 is rough, adhesion between the rib 16 and the encapsulation substrate 18 is improved.

In the aforementioned OLED display 10, a black matrix may be provided on the encapsulation substrate 18. As the black matrix, a pigment such as chrome material and carbon black is used. The black matrix is provided on a part of the encapsulation substrate 18 through which light emitted from the OLED devices 14 is not passed. The black matrix is brought into intimate contact with the rib 16.

The black matrix can reduce diffused reflection of light from the rib 16 which is made of resin. Further, the black matrix can prevent lights of adjacent pixels from being mixed, so that the picture image of the OLED display 10 is sharp.

A surface of the black matrix may be made rough by treating it with a silane coupling agent so as to increase an adhesion to the rib 16. By providing the black matrix on the encapsulation substrate 18, the OLED display 10 can be used as a top-emission OLED display. If the height of the rib 16 is constant, no interference pattern appears on the encapsulation substrate 18 and therefore a display quality can be increased.

A method of producing the aforementioned OLED display 10 will be described. (1) The device substrate 12 and the encapsulation substrate 18 are prepared. (2) A plurality of the OLED devices 14 are formed in the form of a matrix on the device substrate 12. (3) The rib 16 is formed on the device substrate 12 in such a manner that the rib 16 encloses the respective OLED devices 14. (4) The rib 16 and the encapsulation substrate 18 are brought into close contact with each other. (5) The sealant 20 is provided between a marginal area of the device substrate 12 and a marginal area of the encapsulation substrate 18 so as to encapsulate the OLED devices 14.

The order of the aforementioned steps (2) and (3) may be reversed in some cases. This will be described as follows. In the process of producing the passive-matrix OLED display 10, the rib 16 is formed after producing the scanning lines, signal lines, and anode electrodes. In the process of producing the active-matrix OLED display 10, after producing the scanning lines, signal lines, and TFTs, the anode electrodes are formed and then the rib 16 is formed.

Since the OLED devices 14 are encapsulated by the device substrate 12, the encapsulation substrate 18, and the rib 16 by the aforementioned method, oxygen and moisture is not likely to reach to the OLED devices 14. Further, both the OLED devices 14 and the rib 16 are encapsulated by the sealant 20, so that reaction gas emitted from the sealant 20 is not likely to reach to the OLED devices 14.

The aforementioned step (4) may comprise the step of depressurizing the spaces between the OLED devices 14, the encapsulation substrate 18, and the rib 16. When the OLED display 10 in which the rib 16 and the encapsulation substrate 18 are brought into intimate contact with each other under a reduced pressure is brought back to the atmospheric pressure, the adhesion between the rib 16 and the encapsulation substrate 18 is increased. For example, the aforementioned reduced pressure ranges from about 0.01 to 30 kPa, preferably from 1 to 10 kPa.

Before performing the aforementioned step (4), a surface of the encapsulation substrate 18 may be UV/ozone-treated, plasma-treated, or treated with a silane coupling agent. Such surface treatment makes the surface of the encapsulation substrate 18 rough, so that the adhesion between the encapsulation substrate 18 and the rib 16 is improved.

Before performing the aforementioned step (4), a black matrix may be formed on the encapsulation substrate 18. The black matrix is formed by depositing a chrome material by a sputtering deposition method, for example. Alternatively, the black matrix is formed by providing a resist layer containing pigment such as carbon black and then patterning it. In this case, the aforementioned step (4) comprises the step of bringing the black matrix into intimate contact with the rib 16. In some cases, the light emitted from the OLED devices 14 may reflect diffusely from the rib 16. However, the black matrix reduces such diffused reflection. Further, a surface of the black matrix may be treated with a silane coupling agent so as to make the surface rough. This increase the adhesion between the black matrix and the rib.

When the black matrix is formed, the method of the present invention further comprises: providing alignment marks on the device substrate 12 and the encapsulation substrate 18; and aligning the black matrix with the rib 16 using the alignment marks. The alignment marks are provided by printing them on the marginal area of the substrates 12 and 18 or scratching the marginal area of the substrates 12 and 18. With reference to the alignment marks, a known CCD (charge coupled device) camera automatically aligns the black matrix with the rib 16 so that the black matrix can be brought into intimate contact with the rib 16. An accurate and automatic alignment can be achieved by the alignment marks.

According to the method of the present invention, the rib 16 is brought into intimate contact with the encapsulation substrate 18 under a reduced pressure. Therefore, when the OLED display 10 is brought back to the atmospheric pressure, the adhesion between the rib 16 and the encapsulation substrate 18 is increased. As the result, the OLED devices 14 are securely encapsulated, so that oxygen and moisture is hard to get into the OLED display 10 from the outside.

FIG. 2 shows an active-matrix OLED display 22 to which the present invention is applied. In the OLED display 22, TFTs 34 and wiring are formed on the device substrate 12, and polymer 38 is deposited on them. On the polymer 38 is formed the OLED device 24 in which an organic light emitting layer 30 is sandwiched between the anode electrode 26 and the cathode electrode 28. The OLED device 24 is connected to the wiring through a via hole 36. Further, an insulating layer 40 is provided on a predetermined part of the polymer 38, and a rib 32 made of resin is formed on the insulating layer 40. The top of the rib 32 is brought into intimate contact with the encapsulation substrate 18. As is the case with the structure shown in FIG. 1(b), the rib 32 encloses the respective OLED devices 24. The same effect as described with reference to FIGS. (a) and 1(b) can be obtained.

According to the OLED display 10 of the present invention, since the OLED devices 14 are encapsulated by not only the sealant 20 but also the rib 16, oxygen and moisture are hard to get into the OLED display 10 from the outside. Further, the gas emitted from the sealant 20 is blocked by the rib 16, so that the gas is hard to reach to the OLED devices 14. The rib 16 is brought into intimate contact with the encapsulation substrate 18. Therefore, by making the height of the rib 16 constant, no interference pattern appears on the encapsulation substrate 18. Thus, the display quality of the top-emission OLED display 10 is not degraded.

While the embodiments of the present invention have thus been described, it should be understood that the present invention be not limited to the aforementioned embodiments. For example, in the aforementioned embodiments, the respective OLED devices 14 are enclosed by the single rib 16. However, as shown in FIG. 3, respective groups of the OLED devices 14 may be enclosed by a single rib 42. In this case, the rib 42 is brought into intimate contact with the encapsulation substrate 18 in a so-called display area where the OLED devices 14 are provided. Therefore, since no interference pattern appears on the encapsulation substrate 18, the OLED display 10 has a high display quality.

On the periphery of the display area, dummy cells may be provided. The dummy cells are also enclosed by the rib 16. Since the dummy cells are additionally provided, oxygen and moisture are harder to reach to the OLED devices in the display area.

While the embodiments of the present invention have thus been described with reference to the drawings, it should be understood that the present invention be not limited to the aforementioned embodiments. Various changes, modifications, and improvements can be made to the embodiments on the basis of knowledge of those skilled in the art without departing from the scope of the present invention. This application claims priority from Japanese Patent Application No. 2003-209198, which is incorporated herein by reference.

1. An OLED display comprising:
a device substrate;
a plurality of OLED devices provided on the device substrate;
a rib provided on the device substrate in such a manner that the rib encloses the respective OLED devices or respective groups of the OLED devices;
an encapsulation substrate placed opposite to the device substrate and brought into tight contact with the rib; and
a sealant which encapsulates both the OLED devices and the rib, said sealant provided between a marginal area of the device substrate and a marginal area of the encapsulation substrate.

2. The OLED display according to claim 1, wherein a surface of said encapsulation substrate is UV/ozone-treated, plasma-treated, or treated with a silane coupling agent.

3. The OLED display according to claim 1, wherein a black matrix is provided on said encapsulation substrate and said black matrix is brought into intimate contact with the rib.

4. A method of producing an OLED display, comprising: preparing a device substrate and an encapsulation substrate;
forming a plurality of OLED devices on the device substrate;
forming a rib on the device substrate in such a manner that the rib encloses the respective OLED devices or respective groups of the OLED devices;
bringing the rib and the encapsulation substrate into intimate contact with each other; and
encapsulating the OLED devices by a sealant, said sealant provided between a marginal area of the device substrate and a marginal area of the encapsulation substrate.

5. The method of producing an OLED display according to claim 4, wherein said step of bringing the rib and the encapsulation substrate into intimate contact with each other comprises the step of depressurizing spaces between the device substrate, the encapsulation substrate, and the rib.

6. The method of producing an OLED display according to claim 4, wherein a surface of said encapsulation substrate is UV/ozone-treated, plasma-treated, or treated with a silane coupling agent.

7. The method of producing an OLED display according to claim 4, further comprising forming a black matrix on the encapsulation substrate, wherein said step of bringing the rib and the encapsulation substrate into intimate contact with each other comprises bringing the rib and the black matrix into intimate contact with each other.

8. The method of producing an OLED display according to claim 7, further comprising:
forming alignment marks on the device substrate and the encapsulation substrate; and
aligning the black matrix with the rib using the alignment marks.
